(19) United States
(12) Patent Application Publication
(10) Pub. No.: US 2024/0063039 A1
(43) Pub. Date: Feb. 22, 2024

(54) APPARATUS AND METHOD OF DETECTING WAFER EDGE USING LASER SCANNER, AND SEMICONDUCTOR TRANSFER DEVICE

(71) Applicant: SEMES CO., LTD, Chungcheongnam-do (KR)

(72) Inventors: Hee Jae BYUN, Chungcheongnam-do (KR); Chang Rak Baek, Chungcheongnam-do (KR); Kyo Bong Kim, Chungcheongnam-do (KR); Chan Young Choi, Chungcheongnam-do (KR); Wan Hee Jeong, Chungcheongnam-do (KR); Ki Won Han, Chungcheongnam-do (KR); Sang Oh Kim, Chungcheongnam-do (KR)

(21) Appl. No.: 18/135,681

(22) Filed: Apr. 17, 2023

(30) Foreign Application Priority Data
Aug. 22, 2022 (KR) 10-2022-0104791

(51) Int. Cl. H01L 21/67; H01L 21/687

(52) U.S. Cl. CPC H01L 21/67259; H01L 21/68707

(57) ABSTRACT

An apparatus and method of detecting a wafer edge using a laser scanner, and a semiconductor transfer device are provided. The apparatus for detecting a wafer edge using a laser scanner includes a laser scanner disposed on a rear side of a mounted wafer and radiating a laser to a portion of an edge of the wafer, and a detection unit receiving an image acquired by the laser scanner and detecting the wafer edge in the image. The detection unit determines whether each wafer is present or aligned according to wafer edges detected in a plurality of wafer areas in the image.

### CROSS-REFERENCE TO RELATED APPLICATION(S)

This application claims benefit of priority to Korean Patent Application No. 10-2022-0104791 filed on Aug. 22, 2022 in the Korean Intellectual Property Office, the disclosure of which is incorporated herein by reference in its entirety.

### BACKGROUND

### 1. Field

The present disclosure relates to an apparatus and method of detecting a wafer edge using a laser scanner, and a semiconductor transfer device, and more particularly, to an apparatus and method of detecting the presence or absence of a wafer or alignment of a wafer simultaneously, by detecting a plurality of wafer edges using a single laser scanner, and a semiconductor transfer device including the same.

### 2. Description of Related Art

Semiconductor devices such as integrated circuit elements may generally be formed by repeatedly performing a series of processing operations on a substrate, such as a silicon wafer. For example, by repeatedly performing a deposition process of forming a film on a wafer, an etching process for forming the film into patterns having electrical properties, an ion implantation process or diffusion process for implanting or diffusing impurities into the patterns, and a cleaning and rinsing process for removing impurities from the wafer on which the patterns are formed, the semiconductor devices may be formed on the wafer.

Before carrying out the above process, in detail, it is necessary to align the wafer before performing the cleaning and rinsing process, and the wafer alignment may be obtained by acquiring a wafer image using a camera and rotating the wafer chuck or stage such that the wafer is located in a predetermined direction using the wafer image.

In detail, in the patent literature of the related art, wafer alignment is determined using a diffuse reflective sensor in which the light receiving part is located higher than the light emitting part with respect to the attaching plane, and at the same time, the line segment connecting the light receiving part and the light emitting part forms an angle of 82 to 89 degrees with the normal line of the attaching plane.

However, since a light receiving part and a light emitting part should be installed for each wafer to align the wafers as described above, there is a problem in that the number of sensors is required as much as the number of wafers. In order to determine the presence or absence of wafers or wafer alignment for a plurality of wafers stacked in the vertical direction, there are disadvantages due to limitations such as interface management and component arrangement/electrical design.

In addition, in the case of a commonly used die-to-die comparison method, since respective dies on the wafer should be all compared, the time required for the wafer inspection process is further increased.

### SUMMARY

An aspect of the present disclosure is to provide an apparatus and method of detecting a wafer edge using a laser scanner capable of determining whether a wafer is present or aligned for a plurality of stacked wafers at once using a single laser scanner, and a semiconductor transfer device.

According to an aspect of the present disclosure, an apparatus for detecting a wafer edge using a laser scanner includes a laser scanner disposed on a rear side of a mounted wafer and radiating a laser to a portion of an edge of the wafer; and a detection unit receiving an image acquired by the laser scanner and detecting the wafer edge in the image. The detection unit determines whether each wafer is present or aligned according to wafer edges detected in a plurality of wafer areas in the image.

According to an aspect of the present disclosure, a semiconductor transfer device includes a wafer seating portion configured to support a wafer; a robot arm seating the wafer on the wafer seating portion; one laser scanner disposed on the robot arm located on a rear side of the wafer and radiating a laser to an edge of the wafer seated on the wafer seating portion; and an interface unit including a detection unit receiving an image acquired by the laser scanner and detecting a wafer edge in the image, and a communication unit communicating with the robot arm and the laser scanner. The detection unit measures a distance to a position of the wafer or the wafer seating portion corresponding to a laser irradiation direction in the image, and detects a presence or an absence of the wafer according to a peak distance for each predetermined vertical area.

According to an aspect of the present disclosure, a method of detecting a wafer edge using a laser scanner includes acquiring an image by radiating a laser toward a wafer at a constant angle from a rear side of the wafer; measuring a distance to a position of the wafer or a wafer seating portion corresponding to a laser irradiation direction in the image; and detecting whether the wafer is present or not according to a peak distance among distances measured for respective predetermined vertical areas.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 illustrates a perspective view of a semiconductor transfer device according to an embodiment;

FIG. 2 is a plan view of a semiconductor transfer device according to an embodiment;

FIG. 3 schematically illustrates a process of scanning a wafer by an apparatus for detecting a wafer edge using a laser scanner according to an embodiment;

FIG. 4 illustrates a process of determining the presence of a wafer by detecting a wafer edge by an apparatus for detecting a wafer edge using a laser scanner according to an embodiment;

FIG. 5 illustrates a process of determining whether a wafer is aligned by detecting a wafer edge by an apparatus for detecting a wafer edge using a laser scanner according to an embodiment;

FIG. 6 is a flow chart of a method of detecting a wafer edge using a laser scanner according to an embodiment;

FIG. 7 illustrates a detailed process of a method of detecting a wafer edge using a laser scanner according to an embodiment; and

FIG. 8 illustrates a detailed process of a method of detecting a wafer edge using a laser scanner according to an embodiment.

### DETAILED DESCRIPTION

Hereinafter, embodiments will be described in detail so that those skilled in the art may easily practice the present disclosure with reference to the accompanying drawings. However, in describing an embodiment in detail, if it is determined that a detailed description of a related known function or configuration may unnecessarily obscure the gist of the present disclosure, the detailed description will be omitted. In addition, the same reference numerals are used throughout the drawings for parts having similar functions and actions. In addition, in the present specification, terms such as ‘on’, ‘upper portion’, ‘upper surface’, ‘below’, ‘lower portion’, ‘lower surface’, ‘side’ and the like are based on the drawings, and may be changed depending on the direction in which components are actually disposed.

In addition, throughout the specification, when a part is said to be ‘connected’ to another part, it is not only ‘directly connected’, but also ‘indirectly connected’ with other components therebetween. Further, ‘including’ a certain component means that other components may be further included, rather than excluding other components unless otherwise stated.

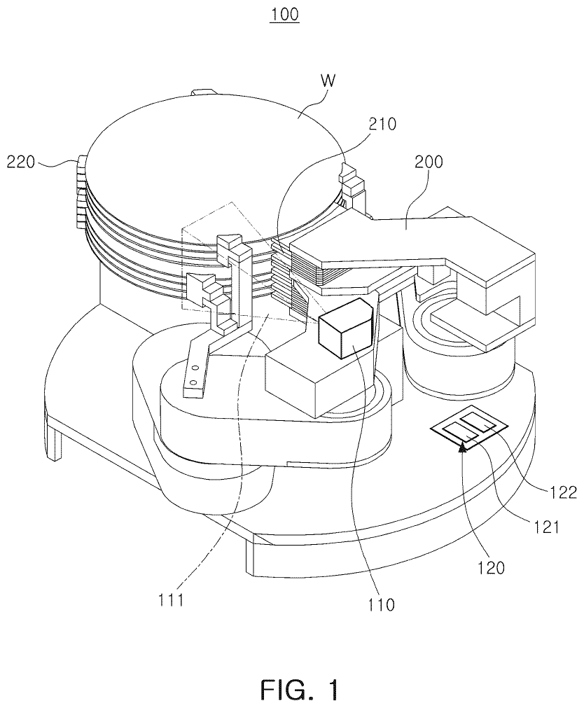

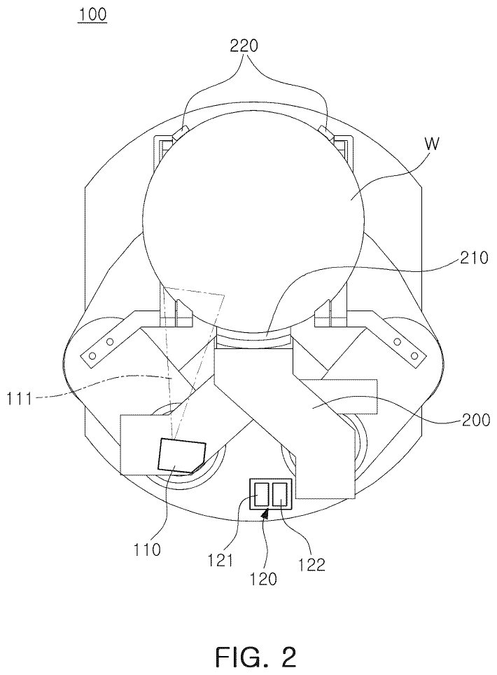

FIGS. 1 and 2 illustrate a perspective view and a plan view of a semiconductor transfer device 100 according to an embodiment.

Referring to FIGS. 1 and 2, a semiconductor transfer device 100 according to an embodiment may include a wafer seating portion 210 configured to support a wafer W, a robot arm 200 for seating the wafer W on the wafer seating portion 210, one laser scanner 110 disposed on the robot arm 200 located at the rear side of the wafer W and radiating a laser to the edge of the wafer W seated on the wafer seating portion 210, and an interface unit 120 including a detection unit 121 receiving an image acquired by the laser scanner 110 and detecting a wafer edge in the image and a communication unit 122 communicating with the robot arm 200 and the laser scanner 110.

In the semiconductor transfer device 100, when the robot arm 200 places the wafer W on the wafer seating portion 210, the wafer W may be fixed by a plurality of wafer fixing parts 220.

At this time, after determining whether or not the wafer W is seated on the wafer seating portion 210 and whether or not the wafer W is properly aligned, the wafer W is fixed with the wafer fixing part 220.

To this end, an apparatus for detecting a wafer edge using the laser scanner 110 according to an embodiment is provided, and the apparatus may include a laser scanner 110 disposed on the rear side of the seated wafer W and radiating a laser to a portion of the edge of the wafer W, and a detection unit 121 for receiving an image obtained by the laser scanner 110 and detecting a wafer edge in the image.

In addition, the laser scanner 110 may be one laser scanner 110, and the detection unit 121 may be an interface board that is connected to the laser scanner 110 by forming one channel and transmits data to an external device.

In detail, one laser scanner 110 and one interface board are connected one-to-one to transmit/receive wafer state data including presence or absence and alignment of a plurality of wafers W.

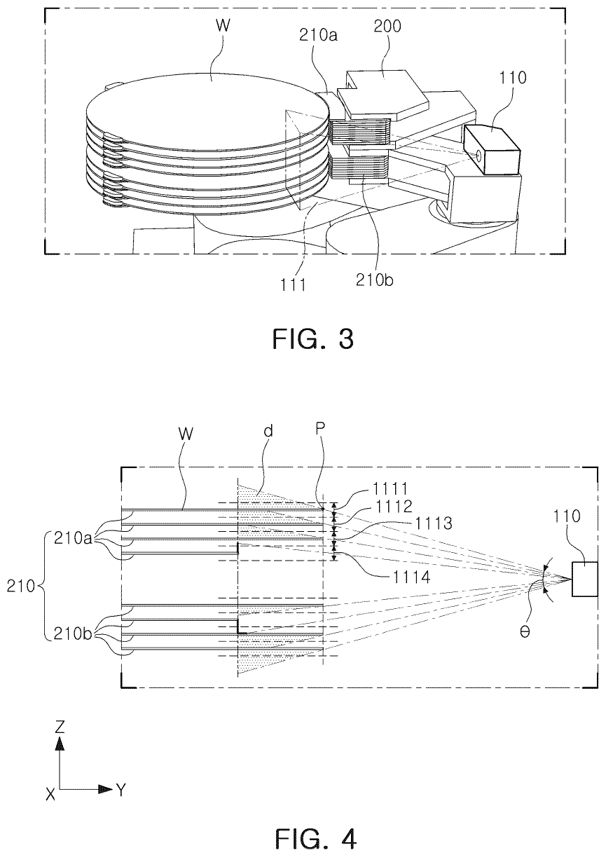

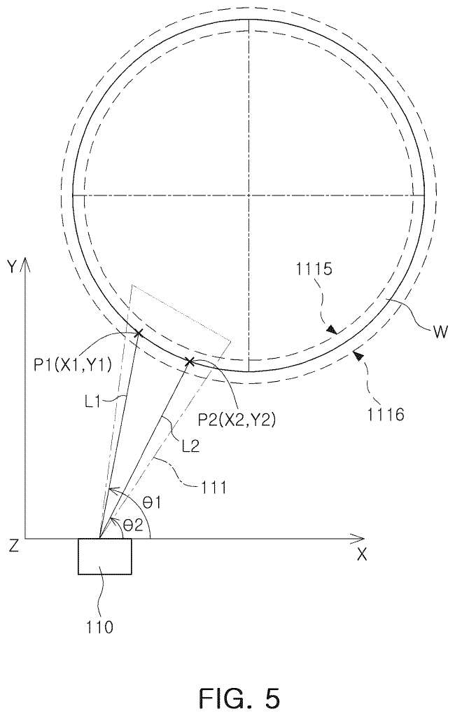

FIG. 3 schematically illustrates a process of scanning a wafer W by an apparatus for detecting a wafer edge using a laser scanner 110 according to an embodiment, and FIGS. 4 and 5 illustrate a process in which the apparatus for detecting a wafer edge using the laser scanner 110 according to an embodiment detects a wafer edge to determine whether a wafer is present or whether the wafer is aligned.

According to an embodiment, the detection unit 121 may determine whether each wafer is present or aligned according to wafer edges detected in a plurality of wafer areas in the image.

As an embodiment, the detection unit 121 may measure the distance to a position of the wafer (W) or the wafer seating portion corresponding to the laser irradiation direction in the image, and may detect the presence or absence of the wafer W according to the peak distance for each of the preset vertical areas 1111, 1112, 1113, and 1114.

In this case, the predetermined vertical areas 1111, 1112, 1113, and 1114 are areas divided based on a cross area between the wafer edge and the laser of the laser scanner 110.

In detail, as illustrated in FIG. 3, the wafer W may be divided into an upper hand and a lower hand, and for example, four wafer seating portions 210a may be provided in the upper hand and four wafer seating portions 210b may be provided in the lower hand.

The robot arm 200 may check which wafer seating portion 210 among the plurality of wafer seating portions 210 is empty and may seat the wafer W on the wafer seating portion 210. To determine whether the wafer seating portion 210 is empty or whether the wafer W is seated thereon, the laser scanner 110 scans a portion of the edge of the wafer seating portion 210a and the interface unit 120 may transmit scan results to the robot arm 200.

The laser scanner 110 according to an embodiment may be disposed at a different height from the wafer W to have a constant field of view (FoV) with respect to the plurality of wafers W.

As illustrated in FIG. 3, the laser scanner 110 and the wafer seating portion 210 may be disposed at different heights, such that the laser scanner 110, and the wafer seating portion 210 on which the edge of each wafer (W) or each wafer (W) is seated, may maintain a constant angle.

In detail, the laser scanner 110 may be disposed lower than the wafer seating portion 210.

Also, as an example, a wafer measurement distance according to a focal range of the laser scanner 110 may pass the front edge of the wafer. The laser scanner 110 scans a portion of the edge of the wafer W, and to accurately scan the edge of the wafer W, the focal range of the laser scanner 110 may be longer than the distance between the laser scanner 110 and the wafer seating portion 210.

In addition, the detection unit 121 according to an embodiment may determine the presence of a wafer according to the first location information of the wafer edge scanned by the laser scanner 110.

As illustrated in FIG. 4, the laser scanner 110 may scan the upper wafer seating portion 210a and the lower wafer seating portion 210b.

In FIG. 4, dotted lines in the horizontal direction are lines dividing the preset vertical areas 1111, 1112, 1113, and 1114. When the wafer w is seated on the wafer seating portion 210, the area is divided in the vertical direction based on a dead zone (d) formed when the wafer edge and the laser of the laser scanner 110 cross.

For example, when measuring the distance from the laser scanner 110 to the wafer W or the wafer seating portion 210 based on a vertical line, a jagged dead zone (d) height is formed. The vertical areas 1111, 1112, 1113, and 1114 may be preset as regions having a constant width around the peak distance p at which the dead zone d starts to form.

Therefore, as illustrated in FIG. 4, the laser scanner 110 irradiates the laser at a constant angle θ, and the detection unit 121 may compare the peak distance p measured in the vertical areas 1111, 1112, 1113, and 1114 with the reference distance measured when the wafer is present, to determine whether there is a wafer W for each of the vertical areas 1111, 1112, 1113, and 1114.

As in the vertical area 1111, when the measured peak distance is equal to the reference distance measured when the wafer W is present or within a certain range thereof, it may be determined that the wafer W is present.

On the other hand, when the wafer W is not present as in the vertical area 1114, there is no peak distance p at which the dead zone d starts to form, and since a distance different from the reference distance measured when the wafer W is present is measured, it may be determined that the wafer W is not present.

In detail, the laser scanner 110 acquires one position with respect to the edge of the wafer W, and the one position means values where (X, Y) are the same. For example, the presence or absence of a wafer may be determined by extracting first location information having a value of (X, Y) and comparing a measurement distance obtained from the first location information with a reference distance.

On the other hand, as illustrated in FIG. 5, the detection unit 121 according to an embodiment may acquire at least one of randomly extracted first location information P1 and second location information P2 by measuring the distance from the laser scanner 110 to the wafer edge in the image, and may detect whether the wafer W is detached by comparing at least one of the first location information P1 and the second location information P2 with an inner limit 1115 and an outer limit 1116 of the wafer seating portion 210.

In detail, the laser scanner 110 may form a sensing area 111 on a portion of the wafer (W) by scanning a laser beam on a portion of the wafer (W). The laser scanner 110 may irradiate laser at a plurality of angles θ, and obtain a distance from the laser scanner 110 to the edge of the wafer W at a specific angle. For example, the detection unit 121 may know from the laser scanner 110 that the distance L1 is measured at the angle θ1 and the distance L2 is measured at the angle θ2. Alternatively, the detection unit 121 already knows mechanical information on the semiconductor transfer device 100, and thus, may obtain angle (θ1, θ2) information from the mechanical information, and obtain only the distance (L1, L2) values measured at each angle from the laser scanner 110.

Then, P1 (X1, Y1) and P2 (X2, Y2) may be obtained using the above values. It can be seen that P1 (L1 cos θ1, L1 sin θ1) and P2 (L2 cos θ2, L2 sin θ2) coordinates are obtained.

In detail, coordinate values of at least two positions of the edge of the wafer W may be obtained using angle and distance values obtained from the laser scanner 110 or the semiconductor transfer device 100. The at least two positions refer to positions having the same Z-axis coordinates and different (X, Y) positions.

As an embodiment, the at least two locations, for example, the first location information (P1) and the second location information (P2), the inner limit 1115 and the outer limit 1116 set at the coordinates of the first location information P1, and the coordinates of the inner limit 1115 and the outer limit 1116 set in the coordinates of the second location information P2 may be compared.

In this case, the size of the wafer (W) is approximately 300 mm in diameter, and the wafer guide is approximately 303 mm in diameter, and therefore, the inner limit 1115 and the outer limit 1116 may be set within the range of ±3 mm. The range may be set using mechanical information.

Therefore, it may be determined whether the wafer W is positioned and aligned between the inner limit 1115 and the outer limit 1116 preset according to the instrument seating limit, or whether the position is outside of the range of the inner limit 1115 and the outer limit 1116.

On the other hand, as another embodiment, to determine whether the wafer (W) is aligned, the coordinates of one position of the edge of the wafer (W) are obtained, which are provided as the first location information P1, and the first location information P1 may be compared with the inner limit 1115 and the outer limit 1116 set at the coordinates of the first location information P1.

Since the inner limit 1115 and the outer limit 1116 are set for each (X, Y) coordinate, whether or not the wafer W is detached may be detected using the first location information P1 for one position, but since a notch is formed on the wafer W to determine the front direction and the notch has a different curvature from the edge of the other wafer (W), when either of the first location information P1 or the second location information P2 is a notch, even if the wafer W is aligned, one of the first location information P1 or the second location information P2 may be outside of the range of the inner limit 1115 and the outer limit 1116.

Therefore, when an error range obtained by comparing the limits 1115 and 1116 of the wafer seating portion 210 with at least one of the first location information P1 and the second location information P2 is outside of a preset error range, the detection unit 121 according to an embodiment may delete at least one of the first location information P1 and the second location information P2 and use the other thereof to determine whether the wafer W is aligned.

In detail, when it is determined that the first location information P2 and the second location information P2, which are two candidate locations, are extracted, and at least one of the first location information P1 and the second location information P2 is a notch; location information determined to be a notch may be deleted, and it may be determined whether or not to be out the inside limit 1115 and the outside limit 1116 using other location information.

Therefore, the detection unit 121 according to an embodiment may determine whether the wafer (W) is aligned, according to at least one of first location information P1 and second location information P2 of the edge of the wafer W scanned by the laser scanner 110. In detail, the detection unit 121 may measure the distance (L) from the laser scanner 110 to the edge of the wafer (W) in the image, to obtain at least one of the randomly extracted first location information P1 and second location information P2, and may detect whether the wafer is detached by comparing at least one of the first location information P1 and the second location information P2 with the limits 1115 and 1116 of the wafer seating portion 210.

In addition, the limits 1115 and 1116 of the wafer seating portion 210 may include an inner limit 1115 or an outer limit 1116 preset in consideration of mechanical characteristics of the wafer W and the wafer seating portion 210.

In addition, when an error range obtained by comparing the limits 1115 and 1116 of the wafer seating portion 210 with at least one of the first location information P1 and the second location information P2 is outside of a preset error range, the detection unit 121 may delete at least one of the first location information P1 and the second location information P2, and may determine whether the wafer is aligned using the other one.

Then, the interface unit 120 according to an embodiment enables the robot arm 200 to enter in the backward direction when at least one of the first location information P1 and the second location information P2 is located inside the inner limit 1115, and when at least one of the first location information P1 and the second location information P2 is located outside the outer limit 1116, the interface unit 120 may move the robot arm 200 in a forward direction.

On the other hand, the detection unit 121 according to an embodiment generates a wafer state according to whether the wafer (W) is present or whether the wafer (W) is aligned, as a flag bit, and may transmit the data set created with the flag bit to the main controller.

A bit may be generated as 1 if the wafer W is present and generated as 0 if the wafer W is not present, and a flag bit for whether a wafer is present may be generated for each angle θ. In addition, when a wafer is present and the alignment is completed by additionally designating a bit about whether the wafer (W) is aligned, a flag bit may be generated as (1, 1), while when the wafer is present but not aligned, the flag bit may be generated as (1, 0), and when the wafer is not present, the flag bit may be generated as (0,0).

The wafer state for each wafer seating portion 210 may be checked only by generating a flag bit for each vertical area and each angle to determine the data set. Accordingly, the moving direction of the robot arm 200 may be determined.

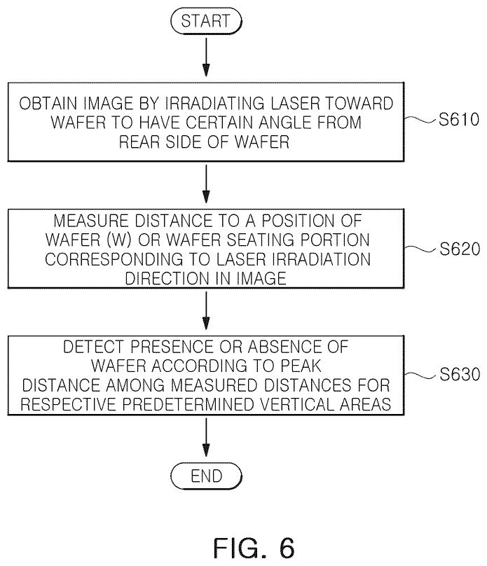

FIGS. 6 to 8 illustrate a flow chart and detailed processes of a method of detecting a wafer edge using a laser scanner 110 according to an embodiment.

As illustrated in FIG. 6, the method of detecting a wafer edge using the laser scanner 110 according to an embodiment may include obtaining an image by irradiating a laser toward the wafer W to have a certain angle from the rear side of the wafer (S610), measuring a distance to a position of the wafer (W) or wafer seating portion 210 corresponding to the laser irradiation direction in the image (S620), and detecting the presence of a wafer W according to a peak distance among the measured distances for respective predetermined vertical areas (S630).

In addition, according to an embodiment, the method of detecting a wafer edge may further include obtaining at least one of the first location information (P1) and the second location information (P2) randomly extracted by measuring the distance to the edge of the wafer (W) corresponding to the laser irradiation direction in the image, and detecting whether the wafer W is detached by comparing at least one of the first location information P1 and the second location information P2 with the inner limit 1115 and the outer limit 1116 of the wafer seating portion 210.

In this case, as an embodiment, in the case in which the error range in which the inner limit 1115 and the outer limit 1116 of the wafer seating portion 210 and at least one of the first location information P1 and the second location information P2 are compared is outside of the preset error range, an operation in which at least one of the first location information (P1) and the second location information (P2) is deleted and whether the wafer is aligned (W) is determined using the other one may be included.

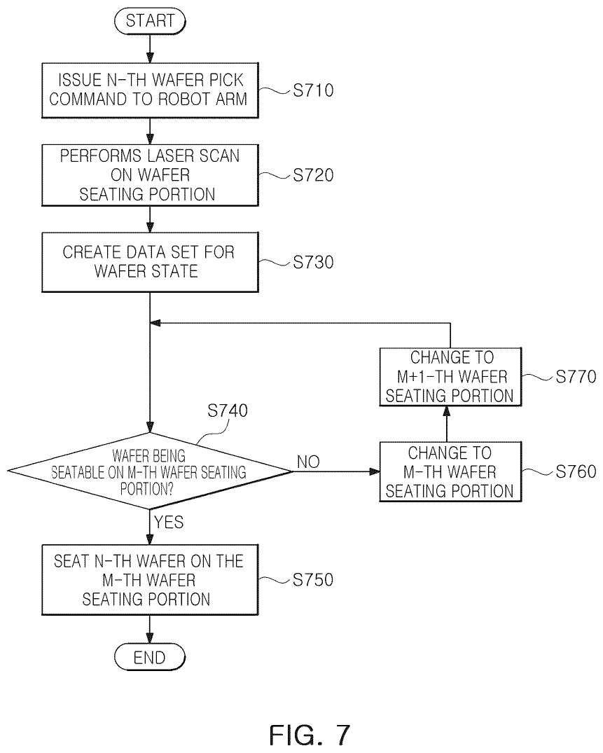

In detail, as illustrated in FIG. 7, the main controller issues an n-th wafer pick command to the robot arm 200 (S710), and the laser scanner 110 performs a laser scan on the wafer seating portion 210 (S720). To safely dispose the picked wafer, the state of the wafer seating portion 210 should be determined, and to this end, the laser scanner 110 performs scanning.

According to the above-described method, a data set for a wafer state may be created (S730). As an example, the data set may include information on whether or not the wafer W is present. The robot arm 200 determines whether the wafer may be seated on the m-th wafer seating portion 210 using the received data set (S740). If the wafer may be seated (Yes in S740), the n-th wafer (W) picked up is seated on the m-th wafer seating portion 210 (S750). For example, it may mean that the data set indicates ‘0’ because the m-th wafer seating portion 210 is empty.

If the seating is impossible (No in S740), the m-th wafer seating portion 210 is removed from the candidate wafer seating portions 210 on which the wafer may be seated (S760), the target is changed to the next wafer seating portion 210, which is the m+1-th wafer seating portion 210 (S770), and then, it is re-determined whether the wafer may be seated on the m+1-th wafer seating portion 210 (S740).

By repeating the above process, the wafer W may be disposed on the empty wafer seating portion 210.

In addition, as an embodiment, a data set may be prepared for each wafer type or hand unit, and the wafer W may be placed on the wafer seating portion 210 based on the data set.

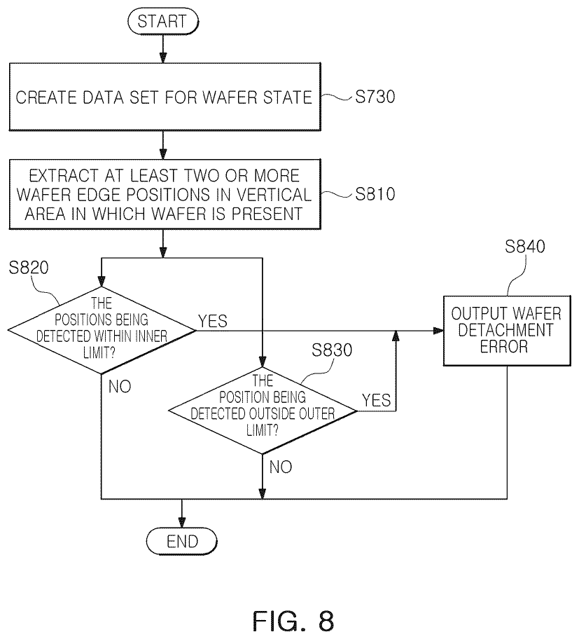

In addition, as illustrated in FIG. 8, a data set on the wafer W may be created (S730). S730 is the same as S730 of FIG. 7. In this case, the data set may include information on the presence or absence of a wafer W and information on whether or not the wafer W is aligned. The following process is a process that proceeds on the premise that the wafer W is present on the wafer seating portion 210.

When the presence and alignment of the wafer W is determined through the above process, at least two or more edge positions of the wafer W may be extracted in the vertical area where the wafer W is present (S810). It may be determined whether at least one of the two or more wafer edge positions is detected within the inner limit 1115 (S820) and whether the position is detected outside the outer limit 1116 (S830). In this case, at least two or more wafer edge positions mean the first location information P1 and the second location information P2.

For example, when the position is not detected within the inner limit 1115 and is not detected outside the outer limit 1116 (No in S820, No in S830), it is determined that the wafer W is aligned in the correct position, and the process may be performed.

On the other hand, if the position is detected within the inner limit 1115 or outside the outer limit 1116 (Yes in S820 or Yes in S830), it is determined that the wafer (W) is detached from the normal position, and a wafer (W) detachment error may be output (S840).

When the wafer (W) detachment error is output (S840), and in the case in which at least one of the first location information P1 and the second location information P2 is located inside the inner limit 1115, the robot arm 200 for transferring the wafer W enters in the backward direction, and when at least one of the first location information P1 and the second location information P2 is located outside the outer limit 1116, the robot arm 200 for transferring the wafer W may be moved in the forward direction.

On the other hand, according to an embodiment, before the method, an operation in which the area is divided according to the dead zone (d) formed by the cross area between the edge of the wafer (W) and the laser irradiated on the edge of the wafer (W) and the vertical area is preset to correspond to the divided area may be further included.

The vertical area may be set in advance by dividing the wafer seating area based on the irradiation angle of the laser scanner 110 and semiconductor device information.

In detail, the detection unit 121 detects a dead zone for each preset channel in the image, and depending on the detected dead zone, the presence or absence of edges of a plurality of wafers may be detected. Details are omitted for clarity of explanation.

In addition, in describing the present disclosure, ‘-part’ or ‘unit’ may be implemented in various manners, for example, by a processor, program instructions executed by the processor, software modules, microcodes, computer program products, logic circuits, application-specific integrated circuits, firmware, or the like.

The contents of the method disclosed in the embodiments of the present application may be directly implemented by a hardware processor, or may be implemented and completed by a combination of hardware and software modules among processors. The software modules may be stored in storage media of the related art such as random access memory, flash memory, read only memory, programmable read only memory or electrically erasable programmable memory, registers, or the like. The storage medium is located in a memory, and the processor reads the information stored in the memory and combines with the hardware to complete the content of the above method. To avoid duplication, detailed descriptions are omitted herein.

In the process of implementation, each content of the above-described method may be completed by a logic integrated circuit of hardware in a processor or instructions in the form of software. The contents of the method disclosed in the embodiments of the present application may be directly implemented by a hardware processor, or may be implemented and completed by a combination of hardware and software modules among processors. The software modules may be stored in storage media of the related art such as random access memory, flash memory, read only memory, programmable read only memory or electrically erasable programmable memory, registers, or the like. The storage medium is located in the memory, and the processor reads the information stored in the memory and combines the same with the hardware to complete the contents of the above method.

For example, those skilled in the art know that it may be implemented by electronic hardware or a combination of computer software and electronic hardware by combining each exemplary unit and algorithm operation described in the embodiments disclosed in this specification. Whether these functions are performed by hardware or software is determined by the specific application of the technical solution and the design constraints. Those Skilled in the art may implement the described functionality using different methods for respective particular applications, but such implementations should not be considered outside the scope of the present application.

In the several embodiments provided in this application, it should be understood that the disclosed devices and methods may be implemented in other manners. For example, the device embodiments described above are merely illustrative, and for example, the division of the unit is only a logical function division, and in actual implementation, other division methods may be provided. For example, a plurality of units or the assembly may be coupled or integrated into one other system, or some features may be ignored or not performed. On the other hand, the couplings or direct couplings or mutual communication connections illustrated or discussed may be indirect couplings or communication connections through some interface, device or unit, and may be electrical, mechanical or other types.

A unit described above as a separate component may be physically separate, and a component indicated as a unit may or may not be a physical unit, for example, may be located in one place or may be distributed over a plurality of network units. According to actual needs, some or all thereof may be selected to realize the purpose of the solution in this embodiment.

For example, each functional unit in each embodiment of the present application may be integrated into one processing unit, each unit may be present alone, or two or more units may be integrated into one unit.

If the function is implemented in the form of a software functional unit and sold or used as an independent product, the function may be stored in a single computer readable storage medium. Based on this understanding, the technical solution of this application essentially or contributed to the related art, or a portion of the technical solution may be implemented in the form of a software product, and the computer software product is stored in a single storage medium. Thus, one computer device (which may be a personal computer, server, network device, or the like), including some instructions, may perform all or a portion of the operations of the method described in each embodiment of the present application. Examples of the above-described storage medium include various media capable of storing program codes, such as a USB memory, a mobile hard disk, a read-only memory (ROM), a random access memory (RAM), a magnetic disk, or a CD-ROM.

As set forth above, according to an embodiment, the presence or alignment of a plurality of stacked wafers may be determined at once using one laser scanner, and the device may be simplified and costs and time may be reduced.

While example embodiments have been illustrated and described above, it will be apparent to those skilled in the art that modifications and variations could be made without departing from the scope of the present disclosure as defined by the appended claims.

What is claimed is:

1. An apparatus for detecting a wafer edge using a laser scanner, comprising:
a laser scanner disposed on a rear side of a mounted wafer and radiating a laser to a portion of an edge of the wafer; and
a detection unit receiving an image acquired by the laser scanner and detecting the wafer edge in the image,
wherein the detection unit determines whether each wafer is present or aligned according to wafer edges detected in a plurality of wafer areas in the image.

2. The apparatus of claim 1, wherein the laser scanner is one laser scanner, and
the detection unit is an interface board connected to the laser scanner by forming one channel and capable of transmitting data to an external device.

3. The apparatus of claim 1, wherein the laser scanner is disposed at a different height from the wafer to have a constant field of view (FoV) for a plurality of wafers, and
is disposed such that a wafer measurement distance according to a focal range of the laser scanner passes a front edge of the wafer.

4. The apparatus of claim 1, wherein the detection unit determines a presence or absence of a wafer according to first location information of the wafer edge scanned by the laser scanner.

5. The apparatus of claim 4, wherein the detection unit measures a distance of the wafer or a wafer seating portion corresponding to a laser irradiation direction in the image, and detects the presence or absence of the wafer according to a peak distance for each predetermined vertical area,
wherein the predetermined vertical area is an area divided based on a cross area between the wafer edge and the laser of the laser scanner.

6. The apparatus of claim 1, wherein the detection unit determines whether the wafer is aligned according to at least one of first location information and second location information of the wafer edge scanned by the laser scanner.

7. The apparatus of claim 6, wherein the detection unit obtains at least one of the first location information and the second location information randomly extracted by measuring a distance from the laser scanner to the wafer edge in the image, and compares the at least one of the first location information and the second location information with a limit of the wafer seating portion to detect whether the wafer is detached.

8. The apparatus of claim 7, wherein the limit of the wafer seating portion includes an inner limit or an outer limit preset in consideration of mechanical characteristics of the wafer and the wafer seating portion.

9. The apparatus of claim 8, wherein the detection unit deletes at least one of the first location information and the second location information and determines whether the wafer is aligned using the other one when an error range provided by comparing the limit of the wafer seating portion with the at least one of the first location information and the second location information is out of a preset error range.

10. The apparatus of claim 1, wherein the detection unit generates a flag bit for a wafer state according to whether the wafer is present or whether the wafer is aligned, and transmits a data set generated with the flag bit to a main controller.

11. A semiconductor transfer device comprising:
a wafer seating portion configured to support a wafer;
a robot arm seating the wafer on the wafer seating portion;
one laser scanner disposed on the robot arm located on a rear side of the wafer and radiating a laser to an edge of the wafer seated on the wafer seating portion; and
an interface unit including a detection unit receiving an image acquired by the laser scanner and detecting a wafer edge in the image, and a communication unit communicating with the robot arm and the laser scanner,
wherein the detection unit measures a distance to a position of the wafer or the wafer seating portion corresponding to a laser irradiation direction in the image, and detects a presence or an absence of the wafer according to a peak distance for each predetermined vertical area.

12. The semiconductor transfer device of claim 11, wherein the predetermined vertical area is an area divided based on a cross area between the wafer edge and the laser of the laser scanner.

13. The semiconductor transfer device of claim 11, wherein the detection unit obtains at least one of randomly extracted first location information and second location information by measuring a distance from the laser scanner to the wafer edge in the image, and
detects whether the wafer is detached by comparing at least one of the first location information and the second location information with an inner limit and an outer limit of the wafer seating portion.

14. The semiconductor transfer device of claim 13, wherein the interface unit causes the robot arm to enter in a backward direction when at least one of the first location information and the second location information is located inside the inner limit, and
moves the robot arm in a forward direction when at least one of the first location information and the second location information is located outside the outer limit.

15. The semiconductor transfer device of claim 13, wherein the detection unit deletes at least one of the first location information and the second location information and determines whether the wafer is aligned using the other one, when an error range obtained by comparing a limit of the wafer seating portion with at least one of the first location information and the second location information is out of a preset error range.

16. A method of detecting a wafer edge using a laser scanner, comprising:
acquiring an image by radiating a laser toward a wafer at a constant angle from a rear side of the wafer;
measuring a distance to a position of the wafer or a wafer seating portion corresponding to a laser irradiation direction in the image; and
detecting whether the wafer is present or not according to a peak distance among distances measured for respective predetermined vertical areas.

17. The method of claim 16, further comprising:
obtaining at least one of randomly extracted first location information and second location information by measuring a distance to a wafer edge corresponding to a laser irradiation direction in the image; and
comparing at least one of the first location information and the second location information with an inner limit and an outer limit of the wafer seating portion to detect whether the wafer is detached.

18. The method of claim 17, wherein when an error range obtained by comparing the inner limit and the outer limit of the wafer seating portion and at least one of the first location information and the second location information is out of a predetermined error range, at least one of the first location information and the second location information is deleted, and whether the wafer is aligned is determined using the other one.

19. The method of claim 17, wherein when at least one of the first location information and the second location information is located inside the inner limit, the robot arm is entered in a backward direction; and
when at least one of the first location information and the second location information is located outside an outer limit, the robot arm is moved in a forward direction.

20. The method of claim 16, further comprising, before the method, dividing an area according to a dead zone formed by a cross area between a wafer edge and a laser irradiated onto the wafer edge, and presetting the vertical area to correspond to the divided area.
